(19) United States
(12) Patent Application Publication
(10) Pub. No.: US 2024/0404938 A1
(43) Pub. Date: Dec. 5, 2024

(54) PACKAGE BODY AND PREPARATION METHOD THEREFOR

(71) Applicant: SKY CHIP INTERCONNECTION TECHNOLOGY CO., LTD., SHENZHEN (CN)

(72) Inventors: Shijie ZHONG, SHENZHEN (CN); Yun LEI, SHENZHEN (CN); Guanqiang SONG, SHENZHEN (CN); Yuhong LI, SHENZHEN (CN); Jing JIANG, SHENZHEN (CN)

(73) Assignee: SKY CHIP INTERCONNECTION TECHNOLOGY CO., LTD., SHENZHEN (CN)

(21) Appl. No.: 18/800,562

(22) Filed: Aug. 12, 2024

Related U.S. Application Data
(63) Continuation of application No. PCT/CN2023/093329, filed on May 10, 2023.

(30) Foreign Application Priority Data
Sep. 22, 2022 (CN) 202211160623.6

(51) Int. Cl. H01L 23/498; H01L 21/56; H01L 21/683; H01L 21/768; H01L 23/00; H01L 25/065; H01L 25/16

(52) U.S. Cl. CPC H01L 23/49838; H01L 21/561; H01L 21/6835; H01L 21/76802; H01L 21/76883; H01L 23/49827; H01L 24/08; H01L 24/80; H01L 24/97; H01L 25/0655; H01L 25/16; H01L 2224/08235; H01L 2224/08238; H01L 2224/80006; H01L 2224/80895; H01L 2224/95001; H01L 2224/97; H01L 2924/3511

(57) ABSTRACT

A method for preparing a package body includes: obtaining a processed plate including a carrier plate arranged with one or more first pads disposed on each of opposite sides thereof and a first plastic packaging layer attached to the each of the opposite sides of the carrier plate; preparing a connecting member on a side of the first plastic packaging layer away from the carrier plate, performing a depth-controlled operation on a preset position of the first plastic packaging layer until a cross section of the connecting member is exposed, and forming a depth-controlled groove; mounting a chip upright in the depth-controlled groove; and forming a second plastic packaging layer on the side of the first plastic packaging layer away from the carrier plate, dividing the carrier plate into at least two package bodies. A package body is also provided.

### CROSS REFERENCE TO RELATED APPLICATIONS

The present application is a continuation-application of International (PCT) Patent Application No. PCT/CN2023/093329, filed May 10, 2023, which claims foreign priority to Chinese Patent Application No. 202211160623.6, filed Sep. 22, 2022, both of which are herein incorporated by reference in their entirety.

### TECHNICAL FIELD

The present disclosure is applied to the field of package bodies, and in particular to a package body and a method for preparing the package body.

### BACKGROUND

A packaging technology is configured to install a housing used for a semiconductor integrated circuit chip. The packaging technology plays a role of placing, fixing, sealing, protecting an electronic component, and enhancing an electrothermal performance. In addition, the packaging technology is a bridge communicating an internal circuit of the electronic component with an external circuit of the electronic component.

A current package body has certain limitations in packaging various components, resulting in insufficient space utilization of the package body.

### SUMMARY OF THE DISCLOSURE

According to a first aspect a method for preparing a package body is provided by some embodiments of the present disclosure. The method includes: obtaining a processed plate, where the processed plate includes a carrier plate and a first plastic packaging layer, the carrier plate is arranged with one or more first pads disposed on each of opposite sides of the carrier plate, and the first plastic packaging layer is attached to the each of the opposite sides of the carrier plate; preparing a connecting member on a side of the first plastic packaging layer away from the carrier plate, performing a depth-controlled operation on a preset position of the first plastic packaging layer until a cross section of the connecting member is exposed, and forming a depth-controlled groove, where the connecting member is connected to a corresponding one of the one or more first pads, and the preset position is partially overlapped with the connecting member; mounting a chip upright in the depth-controlled groove, where a side surface of the chip is connected to the connecting member; and forming a second plastic packaging layer on the side of the first plastic packaging layer away from the carrier plate, dividing the carrier plate into at least two package bodies.

According to a second aspect, a package body is further provided by some embodiments of the present disclosure. The package body includes: a plastic packaging layer, where a depth-controlled groove is defined inside the plastic packaging layer, and one or more pad are arranged on a side of the plastic packaging layer; a chip, accommodated upright in the depth-controlled groove; and a connecting member, where one end of the connecting member is connected to a corresponding one of the one or more first pads, and the other end of the connecting member is connected to a side surface of the chip, such that an electrical signal of the chip is lead out of the package body.

### BRIEF DESCRIPTION OF THE DRAWINGS

FIG. 1 is a flowchart of a method for preparing a package body according to some embodiments of the present disclosure.

FIG. 2 is a flowchart of a method for preparing the package body according to some embodiments of the present disclosure.

FIG. 3 is a structural schematic view of a carrier plate according to some embodiments of the present disclosure.

FIG. 4 is a structural schematic view of the carrier plate according to some embodiments of the present disclosure.

FIG. 5 is a structural schematic view of a processed plate in an operation S21 in the embodiment shown in FIG. 2.

FIG. 6 is a structural schematic view of a processed plate in an operation S22 in the embodiment shown in FIG. 2.

FIG. 7 is a structural schematic view of a processed plate in an operation S23 in the embodiment shown in FIG. 2.

FIG. 8 is a structural schematic view of a processed plate in an operation S24 in the embodiment shown in FIG. 2.

FIG. 9 is a structural schematic view of the package body according to some embodiments of the present disclosure.

FIG. 10 is a structural schematic view of the package body according to some embodiments of the present disclosure.

### DETAILED DESCRIPTION

Technical solutions of the embodiments of the present disclosure will be clearly and completely described below by referring to the accompanying drawings in the embodiments of the present disclosure. Obviously, the described embodiments show only some of, but not all of, the embodiments of the present disclosure. All other embodiments obtained by any ordinary skilled person in the art based on the embodiments in the present disclosure without making creative work shall fall within the scope of the present disclosure.

It should be noted that all directional indications (such as up, down, left, right, forward, backward . . . ) in the present disclosure are used to explain relative positions between components at a particular pose (the pose shown in the accompanying drawings), movements, and so on. When the particular pose changes, the directional indications may change accordingly.

In addition, terms “first” and “second” in the present disclosure are used for descriptive purposes only, and shall not be interpreted as indicating or implying relative importance or implicitly specifying the number of the described technical features. Therefore, features defined by the “first” and the “second” may explicitly or implicitly include at least one such feature. Technical solutions of various embodiments can be combined with each other, but the combination must be achieved by any ordinary skilled person in the art. When technical solutions of the various embodiments contradict each other or combination of the technical solutions cannot be achieved, the combination of the technical solutions shall be interpreted as not existing, and is not within the scope of the present disclosure.

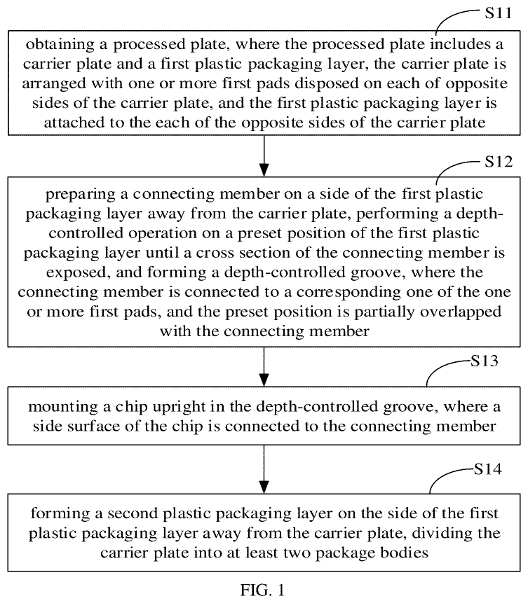

As shown in FIG. 1, FIG. 1 is a flowchart of a method for preparing a package body according to some embodiments of the present disclosure.

In an operation S11, a processed plate is obtained. The processed plate includes a carrier plate and a first plastic packaging layer, the carrier plate is arranged with one or more first pads disposed on each of opposite sides of the carrier plate, and the first plastic packaging layer is attached to the each of the opposite sides of the carrier plate.

The processed plate is obtained. The processed plate includes the carrier plate and two layers of the first plastic packaging layers. Each of the two layers of the first plastic packaging layer is attached to the each of the opposite sides of the carrier plate. That is, the carrier plate is arranged between the two layers of the first plastic packaging layers, and the one or more first pads are arranged on the each of the opposite sides of the carrier plate. When the first plastic packaging layer is attached to the carrier plate, the one or more first pads disposed on a side corresponding to the first plastic packaging layer are also covered by the first plastic packaging layer.

The number of pads disposed on each side of the first plastic packaging layer may be multiple. The pads disposed on the side of the carrier plate may be configured to prepare one or more packaging bodies. The number of the pads disposed on the side of the carrier plate and corresponding to the one or more packaging bodies may be various and determined based on actual needs and is not limited herein.

In some embodiments, the first plastic packaging layer may include at least one selected from the group consisting of an epoxy resin type, a polyimide type, a bismaleimide triazine (BT) type, and a ceramic-based type, which is not limited herein.

The carrier plate is configured to support the preparation of the package body. A material of the carrier plate may include a glass plate, a metal plate, or a plastic plate, which is not limited herein.

In an operation S12, a connecting member is prepared on a side of the first plastic packaging layer away from the carrier plate, a depth-controlled operation is performed on a preset position of the first plastic packaging layer until a cross section of the connecting member is exposed, and a depth-controlled groove is formed. The connecting member is connected to a corresponding first pad, and the preset position is partially overlapped with the connecting member.

After the processed plate is obtained, the connecting member is prepared on the side of the first plastic packaging layer away from the carrier plate, and the connecting member is connected to the corresponding first pad.

In an application, the first plastic packaging layer is drilled from the side of the first plastic packaging layer away from the carrier plate until the first pad is exposed. A hole is metallized until the connecting member connected to the corresponding first pad is formed.

In another application, the depth-controlled operation is performed on the first plastic packaging layer from the side of the first plastic packaging layer away from the carrier plate until the first pad is exposed. Then, a wire or a metal piece is weld on the first pad and is connected to the connecting member. The manner of preparing the connecting member is not limited herein.

After the connecting member is prepared, the depth-controlled operation is performed on the preset position of the first plastic packaging layer until the cross section of the connecting member is exposed, and the depth-controlled groove is formed. The preset position is partially overlapped with the connecting member. The depth-controlled groove is arranged on the connecting member. That is, based on a position of the connecting member, the depth-controlled operation is locally performed until the cross section of the connecting member is exposed, and the depth-controlled groove is formed.

The depth-controlled groove is configured to mount a chip. When a side of the carrier plate is configured to prepare a plurality of package bodies and/or a plurality of chips need to be mounted on one package body, a plurality of depth-controlled grooves may be prepared on the each of the opposite sides of the carrier plate in the operation S12.

A laser depth-controlled manner or a mechanical depth-controlled manner is used in the operation S12 to perform the depth-controlled operation, which is not limited herein.

In an operation S13, a chip is mounted upright in the depth-controlled groove. A side surface of the chip is connected to connecting member.

After the depth-controlled groove is prepared, the chip is mounted upright in the depth-controlled groove. The chip is mounted in each depth-controlled groove. Since a second pad of the chip is arranged on the side surface of the chip, the chip is mounted upright in the depth-controlled groove, and the second pad arranged on the side surface of the chip may be directly connected to the connecting member exposed through the depth-controlled groove. In this way, it may be possible to enable the chip to be mounted upright, so as to simplify a connecting path of the connecting member, thereby improving the space utilization of the package body.

In an application, the second pad arranged on the side surface of the chip may be directly connected to the connecting member exposed through the depth-controlled groove by means of welding. In another application, the second pad arranged on the side surface of the chip may be directly connected to the connecting member exposed through the depth-controlled groove by means of bonding with conductive adhesive, which is not limited herein.

In an operation S14, a second plastic packaging layer is formed on the side of the first plastic packaging layer away from the carrier plate, the carrier plate is divided into at least two package bodies.

After the chip is mounted, the second plastic packaging layer is formed on the side of the first plastic packaging layer away from the carrier plate, so as to perform the plastic packaging on the connecting member and the chip.

In the embodiments, the carrier plate is a double-sided carrier plate, and the preparation of the connecting member, the installation of the chip, and the plastic packaging are performed on each side of the double-sided carrier plate. Therefore, the package body is prepared on the each of the opposite sides of the carrier plate. In this way, by dividing the carrier plate, the at least two package bodies may be obtained. The carrier plate may further be configured to perform batch preparation of the package bodies. After the carrier plate is divided, each of two divided plates is cut, and a plurality of independent package bodies are obtained.

By arranging the double-sided carrier plate, the production of preparing the packaging body may be increased, thereby improving the efficiency of preparing the packaging body.

In the above-mentioned package, a size of system-level package may also be enlarged to exceed 100 mm*300 mm, so as to meet more application needs.

Through the above-mentioned operations, the method for preparing the package body provided in the embodiments includes: preparing the connecting member on the first plastic packaging layer arranged on the each of two sides of the processed plate, performing the local depth-controlled operation based on the position of the connecting member, and forming the depth-controlled groove. In this way, it may be possible to enable the chip to be mounted upright in the depth-controlled groove, such that the second pad arranged on the side surface of the chip may be directly connected to the connecting member exposed through the depth-controlled groove, thereby enabling the chip to be mounted upright. Therefore, a connecting path of the connecting member may be simplified by mounting the chip upright, thereby improving the space utilization of the package body, reducing the limitation of system in panel level package, and expanding an application scenario of the package body. In addition, the double-sided carrier plate is configured to prepare the connecting member, mount the chip, and perform the plastic packaging, such that the package body may be prepared on the each of the opposite sides of the carrier plate. In this way, the production of preparing the packaging body may be increased, thereby improving the efficiency of preparing the packaging body.

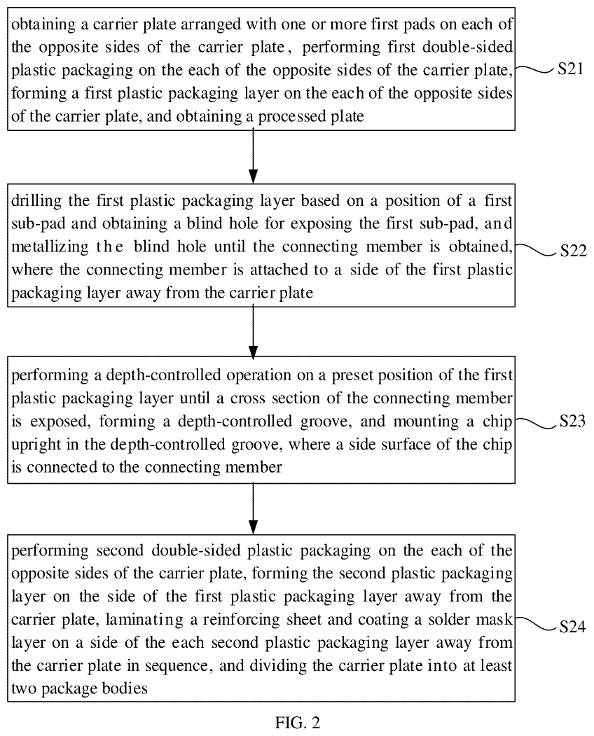

As shown in FIG. 2, FIG. 2 is a flowchart of a method for preparing the package body according to some embodiments of the present disclosure.

In an operation S21, a carrier plate arranged with one or more first pads on each of opposite sides of the carrier plate is obtained, first double-sided plastic packaging is performed on the each of the opposite sides of the carrier plate, a first plastic packaging layer is formed on the each of the opposite sides of the carrier plate, and a processed plate is obtained.

The carrier plate arranged with the one or more first pads on the each of the opposite sides of the carrier plate is obtained. The carrier plate includes a substrate and the one or more first pads arranged on each of opposite sides of the substrate. The number of the one or more first pads arranged on the each of the opposite sides of the substrate may be multiple, such as 4, 8, 11, etc., which may be determined based on actual needs.

In an application, the substrate of the carrier plate includes a conductive layer, a first dielectric layer, and another conductive layer stacked sequentially, and the first dielectric layer is attached to the conductive layer and the another conductive layer.

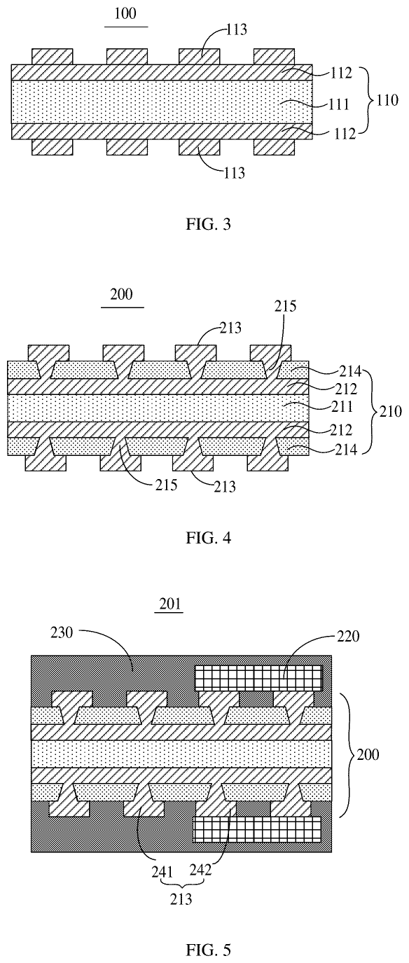

As shown in FIG. 3, FIG. 3 is a structural schematic view of a carrier plate according to some embodiments of the present disclosure.

The carrier plate 100 includes a substrate 110 and one or more first pads 113 arranged on each of opposite sides of the substrate 110.

The substrate 110 includes a conductive layer 112, a first dielectric layer 111, and another conductive layer 112 stacked sequentially, and the first dielectric layer 111 is attached to the conductive layer 112 and the another conductive layer 112.

The number of the pads 113 arranged on each side of the substrate 110 may be multiple.

The carrier plate 100 provided in the embodiments may achieve miniaturization and portability of the package body.

In another application, the substrate of the carrier plate includes a second dielectric layer, a conductive layer, a first dielectric layer, another conductive layer, and another second dielectric layer. A conductive hole is formed on each of the second dielectric layer and the another second dielectric layer and configured to connect the first pad of the carrier plate and a corresponding one of the conductive layer and the another conductive layer.

As shown in FIG. 4, FIG. 4 is a structural schematic view of the carrier plate according to some embodiments of the present disclosure.

In the embodiments, the carrier plate 200 includes a substrate 210 and one or more first pads 213 arranged on each of opposite sides of the substrate 210.

The substrate 210 of the carrier plate 200 includes a second dielectric layer 214, a conductive layer 212, a first dielectric layer 211, another conductive layer 212, and another second dielectric layer 214. A plurality of conductive holes 215 are formed on each of the second dielectric layer 214 and the another second dielectric layer 214, so as to connect the first pad 213 of the carrier plate 200 and a corresponding one of the conductive layer 212 and the another conductive layer 212.

In the embodiments, an inside conductive structure of the carrier plate 200 is I-shaped or Z-shaped, which may enhance the structural stability of the package body and improve the reliability of the package body.

The one or more first pads arranged on the carrier plate may include a first sub-pad and a second sub-pad. The first sub-pad refers to a first pad configured to prepare the connecting member subsequently and a first pad configured to conduct the chip. The second sub-pad refers to a first pad configured to mount a component subsequently. The number of the first sub-pads and the number of the second sub-pads arranged on the carrier plate may be determined based on the number of chips and the number of components, which is not limited herein.

In an application, before performing the first plastic packaging, the component may be mounted on the second sub-pad. In some embodiments, a pad of the component may be welded on a corresponding second sub-pad, or may be connected to the corresponding second sub-pad by means of wire bonding. The component may include any active/passive element, such as the chip, a resistance capacitance element, a power source supply, a switch, etc., and a specific type and the number of the component may be determined based on actual needs.

The first double-sided plastic packaging is performed on the opposite sides of the carrier plate at the same time, the first plastic packaging layer is formed on the each of the opposite sides of the carrier plate, and the processed plate is obtained. A gap between the component and the first pad is filled by the first plastic packaging layer.

Since the first plastic packaging in the operation S21 is double-sided plastic packaging, a force is applied to each of two sides of the carrier plate at the same time during the plastic packaging process, such that forces applied to the first pad and the conductive layer arranged on the carrier plate are balanced during the plastic packaging process. In this way, it may be possible to reduce the occurrence of warpage during a process of preparing the package body, so as to improve the structural stability and reliability of the package body.

As shown in FIG. 5, FIG. 5 is a structural schematic view of a processed plate in an operation S21 in the embodiment shown in FIG. 2.

Based on the embodiments described in FIG. 4, in the embodiments, the first pad 213 is divided into the first sub-pad 241 and the second sub-pad 242. In the embodiments, a case where there are two first sub-pads 241 and two second sub-pads 242 is taken as an example. In other embodiments, there are other numbers of the first sub-pads 241 and other numbers of the second sub-pads 242, which is not limited herein.

A side of each second sub-pad 242 away from the carrier plate 200 is arranged with a component 220. In some embodiments, the component 220 may be weld on the corresponding second sub-pad 242 by using solder paste.

A first plastic packaging layer 230 is attached to each of the opposite sides of the carrier plate 200. The component 220 and the first pad 213 which are arranged on the corresponding side are respectively wrapped by the first plastic packaging layer 230. A gap between the component 220 and the first pad 213 is filled by the first plastic packaging layer 230.

When the carrier plate provided in the embodiments shown in FIG. 3 is used as a basis for performing the subsequent preparation, a structure of the carrier plate is similar to that of the carrier plate provided in the embodiments shown in FIG. 4 and also used as a basis for performing the subsequent preparation, which will not be repeated.

In an operation S22, the first plastic packaging layer is drilled based on a position of the first sub-pad, and a blind hole for exposing the first sub-pad is obtained. The blind hole is metallized until the connecting member is obtained, and the connecting member is attached to the side of the first plastic packaging layer away from the carrier plate.

The first plastic packaging layer is drilled based on the position of the first sub-pad, and the blind hole for exposing the first sub-pad is obtained. The drilling may be performed by means of laser drilling.

The blind hole is metallized until the connecting member is obtained, and the connecting member is attached to the side of the first plastic packaging layer away from the carrier plate. Electroplating, sputtering, or evaporating is performed on the each of the opposite sides of the processed plate until the blind hole is filled, and an electroplated metal layer is formed on the side of the first plastic packaging layer away from the carrier plate. In an application, an unnecessary part may be removed by etching the electroplated metal layer, and the connecting member is formed. In another application, the electroplated metal layer may also be directly taken as the connecting member, and the heat dissipation efficiency of the package body may be improved by increasing an area of the connecting member.

A middle part of the connecting member is attached to the side of the first plastic packaging layer away from the carrier plate. Each end of the connecting member extends to the first sub-pad along the blind hole and is connected to the first sub-pad. The connecting member may include at least two ends. At least one connecting member may be arranged on the side of the first plastic packaging layer away from the carrier plate.

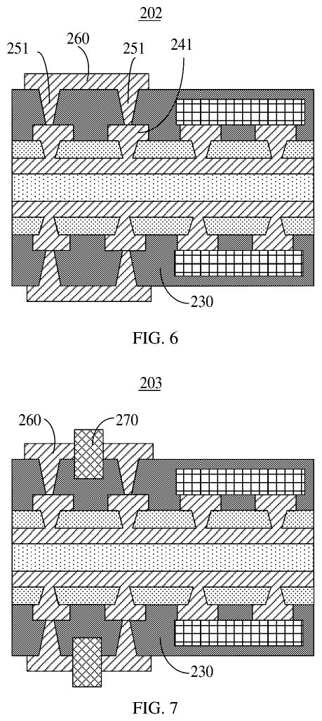

As shown in FIG. 6, FIG. 6 is a structural schematic view of a processed plate in an operation S22 in the embodiment shown in FIG. 2.

Based on the embodiments described in FIG. 5, in a processed plate 202 provided in the embodiments, a blind hole 251 is defined on each of two first plastic packaging layers 230. One first sub-pad 241 is exposed through each blind hole 251. A connecting member 260 is arranged on a side of the first plastic packaging layer 230 away from the first sub-pad 24. Each end of the connecting member 260 extends to the first sub-pad 241 along the blind hole 251 and is connected to the first sub-pad 241.

In an operation S23, a depth-controlled operation is performed on a preset position of the first plastic packaging layer until a cross section of the connecting member is exposed, and a depth-controlled groove is formed. A chip is mounted upright in the depth-controlled groove. A side surface of the chip is connected to connecting member.

The depth-controlled operation is performed on the preset position of the first plastic packaging layer until the cross section of the connecting member is exposed, and the depth-controlled groove is formed. The preset position is partially overlapped with the connecting member. The depth-controlled operation may be performed by one of a mechanical manner, a laser manner, and a chemical manner, so as to form the depth-controlled groove.

The depth-controlled groove is defined on the connecting member. That is, based on the position of the connecting member, the depth-controlled operation is locally performed until the cross section of the connecting member is exposed, and the depth-controlled groove is formed. A groove wall of the depth-controlled groove is formed by the connecting member and the first plastic packaging layer.

The depth-controlled groove is configured to mount the chip. When a side of the carrier plate is configured to prepare a plurality of package bodies and/or a plurality of chips need to be mounted on one package body, a plurality of depth-controlled grooves may be prepared on the each of the opposite sides of the carrier plate in the operation S23.

The chip is mounted upright in the depth-controlled groove, and the side surface of the chip is connected to the connecting member. The chip is mounted in each depth-controlled groove. Since a second pad of the chip is arranged on the side surface of the chip, the chip is mounted upright in the depth-controlled groove, and the second pad arranged on the side surface of the chip may be directly connected to the connecting member exposed through the depth-controlled groove. In this way, it may be possible to enable the chip to be mounted upright, so as to simplify a connecting path of the connecting member, thereby improving the space utilization of the package body.

After the chip is mounted, the chip may be electrically connected to the connecting member, the first sub-pad, the conductive layer, the second sub-pad, and the component in sequence.

As shown in FIG. 7, FIG. 7 is a structural schematic view of a processed plate in an operation S23 in the embodiment shown in FIG. 2.

Based on the embodiments described in FIG. 6, in a processed plate 203 provided in the embodiments, at least one depth-controlled groove (not shown) is defined on the first plastic packaging layer 230, and a chip 270 is mounted upright in the depth-controlled groove. An inner wall of the depth-controlled groove includes a connecting member 260 and the first plastic packaging layer 230. The second pad of the chip 270 is arranged on the side surface of the chip 270 and is connected to the connecting member 260 arranged on the inner wall of the depth-controlled groove. In the embodiments, a second pad may be arranged on each of opposite side surfaces of the chip 270, such that the chip 270 may be connected to two surfaces of the connecting member 260 disconnected by the depth-controlled groove. In other embodiments, the second pad may only be arranged on one surface of the chip 270. The chip 270 is connected to one surface of the connecting member 260 disconnected by the depth-controlled groove. The chip 270 may be fixed with the connecting member 260 by welding.

When the chip 270 is mounted upright in the depth-controlled groove, the second pad arranged on the side surface of the chip 270 may be directly connected to the connecting member 260 exposed through the depth-controlled groove. In this way, it may be possible to enable the chip 270 to be mounted upright, so as to simplify the connecting path of the connecting member 260, thereby improving the space utilization of the package body.

In an operation S24, second double-sided plastic packaging is performed on the each of the opposite sides of the carrier plate, and the second plastic packaging layer is formed on the side of the first plastic packaging layer away from the carrier plate. A reinforcing sheet is laminated and a solder mask layer is coated on the side of the each second plastic packaging layer away from the carrier plate in sequence. The carrier plate is divided into the at least two package bodies.

After the chip is mounted, the second double-sided plastic packaging is performed on the opposite sides of the processed plate, and the second plastic packaging layer is formed on the side of the first plastic packaging layer away from the carrier plate. The chip and the connecting member are covered by the second plastic packaging layer.

In some embodiments, the second plastic packaging layer may include at least one selected from the group consisting of the epoxy resin type, the polyimide type, the BT type, and the ceramic-based type, which is not limited herein.

Since the second plastic packaging in the operation S24 is double-sided plastic packaging, the force is applied to the each of two sides of the processed plate at the same time during the plastic packaging process, such that forces applied to the connecting member arranged on the processed plate are balanced during the plastic packaging process. In this way, it may be possible to reduce the occurrence of warpage during a process of preparing the package body, so as to improve the structural stability and reliability of the package body. In the embodiments, each of the first plastic packaging and the second plastic packaging is the double-sided plastic packaging, it may be possible to improve the balance during the process of preparing the package body, thereby reducing an occurrence of uneven force during the process of preparing the package body. After the second plastic packaging, the first plastic packaging and the second plastic packaging may form an entire plastic packaging layer.

After the second plastic packaging, the reinforcing sheet is laminated and the solder mask layer is coated on the side of each second plastic packaging layer away from the carrier plate in sequence, such that it may be possible to improve the structural rigidity and stability of the package body through the reinforcing sheet. In addition, it may be possible to improve the surface insulation of the package body through the solder mask layer, so as to reduce an occurrence of the short circuit between the package body and other components. The solder mask layer may include an insulating material such as ink.

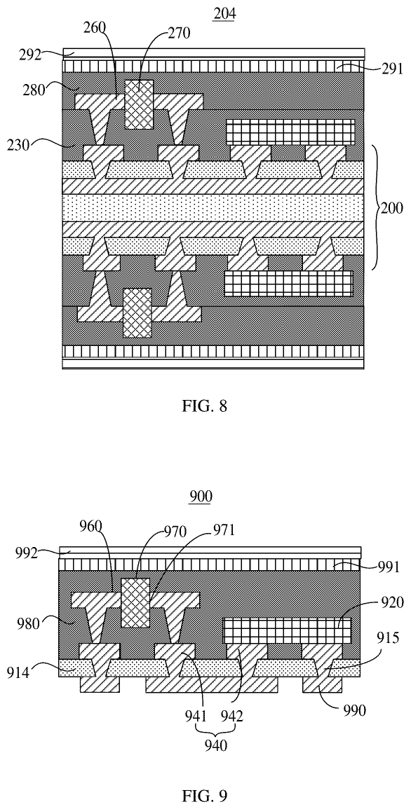

As shown in FIG. 8, FIG. 8 is a structural schematic view of a processed plate in an operation S24 in the embodiment shown in FIG. 2.

Based on the embodiments described in FIG. 7, in a processed plate 204 provided in the embodiments, a second plastic packaging 280 is attached to the side of the first plastic packaging 230 away from the carrier plate 200. The chip arranged on the side corresponding to the second plastic packaging 280 and the connecting member 260 are covered by the second plastic packaging 280.

A reinforcing sheet 291 is attached to the side of the second plastic packaging layer 280 away from the carrier plate 200. A solder mask layer 292 is attached to a side of the reinforcing sheet 291 away from the carrier plate 200.

The carrier plate is divided into the at least two package bodies. In some embodiments, the first dielectric layer of the carrier plate is removed, and the carrier plate is divided. The conductive layer exposed after the carrier plate is divided is graphically etched, a conductive circuit is formed, and the at least two package bodies are obtained. A specific shape of the conductive circuit may be determined based on actual needs, which is not limited herein.

After a protective layer is coated on the surface of the package body, the package body may be put into storage.

In an application, when the carrier plate is configured to perform batch preparation of the package bodies, the carrier plate may be cut after the carrier plate is divided, and a plurality of independent package bodies are obtained.

Through the above-mentioned operations, the method for preparing the package body provided in the embodiments includes: preparing the connecting member on the first plastic packaging layer arranged on the each of two sides of the processed plate, performing the local depth-controlled operation based on the position of the connecting member, and forming the depth-controlled groove. In this way, it may be possible to enable the chip to be mounted upright in the depth-controlled groove, such that the second pad arranged on the side surface of the chip may be directly connected to the connecting member exposed through the depth-controlled groove, thereby enabling the chip to be mounted upright. Therefore, a connecting path of the connecting member may be simplified by mounting the chip upright, thereby improving the space utilization of the package body. In addition, the double-sided carrier plate is configured to prepare the connecting member, mount the chip, and perform the plastic packaging, such that the package body may be prepared on the each of the opposite sides of the carrier plate. In this way, the production of preparing the packaging body may be increased, thereby improving the efficiency of preparing the packaging body. Besides, in the embodiments, each of the first plastic packaging and the second plastic packaging is the double-sided plastic packaging, it may be possible to improve the balance during the process of preparing the package body. Therefore, it may be possible to reduce the occurrence of uneven force and warpage during the process of preparing the package body, thereby improving the structural stability and reliability of the package body.

As shown in FIG. 9, FIG. 9 is a structural schematic view of the package body according to some embodiments of the present disclosure.

In the embodiments, a package body 900 includes a plastic packaging layer 980, a chip 970, and a connecting member 960.

A depth-controlled groove (not shown) is defined inside the plastic packaging layer 980. One or more first pads 940 are arranged on a side of the plastic packaging layer 980. The chip 970 is arranged upright in the depth-controlled groove. The number of chips 970 may be one or more, and the number of connecting members 960 may be one or more, which is not limited herein.

One end of the connecting member 960 is connected to a corresponding first pad 940, and the other end of the connecting member 960 is connected to a side surface of the chip 970, such that an electrical signal of the chip 970 is lead out of the package body 900.

When a second pad 971 is arranged on one side of the chip 970, the one end of the connecting member 960 is connected to the corresponding first pad 940, and the other end of the connecting member 960 is connected to the second pad 971 arranged on the side surface of the chip 970.

When the second pad 971 is arranged on each of two sides of the chip 970, one end of each of two connecting members 960 is connected to the corresponding first pad 940, and the other end of the each of the two connecting members 960 is connected to the second pad 971 arranged on each of opposite sides of the chip 970.

By arranging the above-mentioned structure, in the package body provided in the embodiments, it may be possible to enable the chip to be mounted upright by matching the connecting member with the depth-controlled groove, so as to simplify the connecting path of the connecting member, thereby improving the space utilization of the package body.

In other embodiments, a first sub-pad 941 and a second sub-pad 942 are arranged on a side of the plastic packaging layer 980. That is, the one or more first pads 940 include a first sub-pad 941 and a second sub-pad 942. The first sub-pad 941 refers to the first pad 940 configured to conduct the chip 970 through the connecting member 960. The second sub-pad 942 refers to the first pad 940 configured to mount a component 920.

One end of the connecting member 960 is connected to a corresponding first sub-pad 941, and the other end of the connecting member 960 is connected to the side surface of the chip 970.

The component 920 is mounted on a side of the second sub-pad 942 close to the plastic packaging layer 980.

In other embodiments, a second dielectric layer 914 is arranged on a side of the plastic packaging layer 980. A conductive circuit 990 is arranged on a side of the second dielectric layer 914 away from the plastic packaging layer 980, and a conductive hole 915 is defined on the second dielectric layer 914.

The conductive circuit 990 is connected to a first sub-pad 941 or a second sub-pad 942 through the conductive hole 915.

The component 920 may achieve external connection through the second sub-pad 942, the conductive hole 915, and the conductive circuit 990 in sequence. The chip 970 may achieve external connection through the connecting member 960, the first sub-pad 941, the conductive hole 915, and the conductive circuit 990 in sequence.

The package body 900 provided in the embodiments may be prepared based on the carrier plate provided in the embodiments described in FIG. 4. By preparing the package body 900 provided in the embodiments, the structural stability of the package body may be enhanced and the reliability of the package body may be improved.

The conductive circuit 990 may include an outer pad connected to the pad 940 and a circuit connected to the outer pad.

In other embodiments, a reinforcing sheet 991 may be attached to a side of the plastic packaging layer 980 away from the conductive circuit 990, so as to improve the structural rigidity of the package body 900.

In other embodiments, a solder mask layer 992 may be attached to the side of the enhancement sheet 991 away from the conductive circuit 990, so as to enhance the surface insulation of the package body 900.

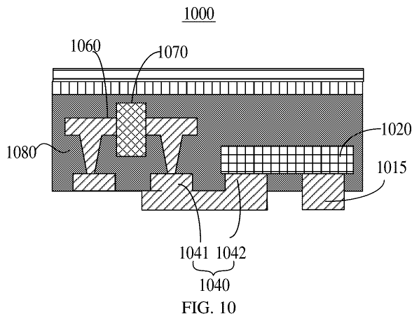

As shown in FIG. 10, FIG. 10 is a structural schematic view of the package body according to some embodiments of the present disclosure.

A position and a connecting relationship between a reinforcing sheet, a solder mask layer, a chip 1070, a connecting member 1060, a plastic packaging layer 1080, a component 1020, one or more first pads 1040, a first sub-pad 1041, and a second sub-pad 1042 of the package body 1000 in the embodiments are the same as those in the foregoing embodiments, which may refer to the above-mention description and will not be repeated.

In the embodiments, a conductive circuit 1015 is attached to a side of the plastic packaging layer 1080. The conductive circuit 1015 is connected to at least part of the first sub-pad 1041 and/or at least part of the second sub-pad 1042, such that the component 1020 may achieve external connection through the second sub-pad 1042 and the conductive circuit 990 in sequence. The chip 1070 may achieve external connection through the connecting member 1060, the first sub-pad 1041, and the conductive circuit 990 in sequence.

The conductive circuit 1090 may include an outer pad connected to the pad 1040 and a circuit connected to the outer pads.

The package body 1000 provided in the embodiments may achieve miniaturization and portability.

The package body 1000 provided in the embodiments may be prepared based on the carrier plate provided in the embodiments described in FIG. 3.

The above description shows only embodiments of the present disclosure and does not limit the scope of the present disclosure. Any equivalent structure or equivalent process transformation performed based on the specification and accompanying drawings, applied directly or indirectly in other related fields, shall be equally covered by the scope of the present disclosure.

What is claimed is:

1. A method for preparing a package body, comprising:
obtaining a processed plate, wherein the processed plate comprises a carrier plate and a first plastic packaging layer, the carrier plate is arranged with one or more first pads disposed on each of opposite sides of the carrier plate, and the first plastic packaging layer is attached to the each of the opposite sides of the carrier plate;
preparing a connecting member on a side of the first plastic packaging layer away from the carrier plate, performing a depth-controlled operation on a preset position of the first plastic packaging layer until a cross section of the connecting member is exposed, and forming a depth-controlled groove, wherein the connecting member is connected to a corresponding one of the one or more first pads, and the preset position is partially overlapped with the connecting member;
mounting a chip upright in the depth-controlled groove, wherein a side surface of the chip is connected to the connecting member; and
forming a second plastic packaging layer on the side of the first plastic packaging layer away from the carrier plate, dividing the carrier plate into at least two package bodies.

2. The method for preparing the package body according to claim 1, wherein the obtaining a processed plate, comprises:
obtaining the carrier plate arranged with the one or more first pads on the each of the opposite sides of the carrier plate;
performing first double-sided plastic packaging on the each of the opposite sides of the carrier plate, forming the first plastic packaging layer on the each of the opposite sides of the carrier plate, and obtaining the processed plate.

3. The method for preparing the package body according to claim 2, wherein the one or more first pads comprise a first sub-pad and a second sub-pad; and
wherein before performing first double-sided plastic packaging on the each of the opposite sides of the carrier plate, forming the first plastic packaging layer on the each of the opposite sides of the carrier plate, and obtaining the processed plate, comprises:
mounting a component on the second sub-pad.

4. The method for preparing the package body according to claim 3, wherein the preparing a connecting member on a side of the first plastic packaging layer away from the carrier plate, comprises:
drilling the first plastic packaging layer based on a position of the first sub-pad and obtaining a blind hole for exposing the first sub-pad;
metallizing the blind hole until the connecting member is obtained, wherein the connecting member is attached to the side of the first plastic packaging layer away from the carrier plate, and each end of the connecting member extends to the first sub-pad along the blind hole and is connected to the first sub-pad.

5. The method for preparing the package body according to claim 4, wherein the metallizing the blind hole until the connecting member is obtained, comprises:
performing electroplating, sputtering, or evaporating on the opposite sides of the processed plate until the blind hole is filled, and forming the connecting member on the side of the first plastic packaging layer away from the carrier plate.

6. The method for preparing the package body according to claim 5, wherein the performing electroplating, sputtering, or evaporating on the opposite sides of the processed plate until the blind hole is filled, and forming the connecting member on the side of the first plastic packaging layer away from the carrier plate, comprises:
performing electroplating, sputtering, or evaporating on the opposite sides of the processed plate until the blind hole is filled, and forming an electroplated metal layer on the side of the first plastic packaging layer away from the carrier plate;
taking the electroplated metal layer as the connecting member; or
forming the connecting member by etching the electroplated metal layer.

7. The method for preparing the package body according to claim 1, wherein the forming a second plastic packaging layer on the side of the first plastic packaging layer away from the carrier plate, dividing the carrier plate into at least two package bodies, comprises:
performing second double-sided plastic packaging on the each of the opposite sides of the carrier plate, and forming the second plastic packaging layer on the side of the first plastic packaging layer away from the carrier plate;
laminating a reinforcing sheet and coating a solder mask layer on a side of the second plastic packaging layer away from the carrier plate in sequence; and
dividing the carrier plate into the at least two package bodies.

8. The method for preparing the package body according to claim 1, wherein the carrier plate comprises a substrate and the one or more first pads arranged on each of opposite sides of the substrate;
the substrate of the carrier plate comprises a conductive layer, a first dielectric layer, and another conductive layer stacked sequentially, and the first dielectric layer is attached to the conductive layer and the another conductive layer; or
the substrate of the carrier plate comprises a second dielectric layer, a conductive layer, a first dielectric layer, another conductive layer, and another second dielectric layer, a conductive hole is formed on each of the second dielectric layer and the another second dielectric layer and configured to connect the pad of the carrier plate and a corresponding one of the conductive layer and the another conductive layer.

9. The method for preparing the package body according to claim 8, wherein the dividing the carrier plate and obtaining at least two package bodies, comprises:
removing the first dielectric layer and dividing the carrier plate;
etching each of the exposed conductive layer and the exposed another conductive layer, and obtaining the at least two package bodies.

10. The method for preparing the package body according to claim 1, wherein the performing a depth-controlled operation on a preset position of the each first plastic packaging layer until a cross section of the connecting member is exposed, and forming a depth-controlled groove, comprises:
performing the depth-controlled operation on the preset position of the first plastic packaging layer by one of a mechanical manner, a laser manner, and a chemical manner until the cross section of the connecting member is exposed, and forming the depth-controlled groove.

11. The method for preparing the package body according to claim 1, wherein an inside conductive structure of the carrier plate is I-shaped or Z-shaped.

12. The method for preparing the package body according to claim 1, wherein the carrier plate is a double-sided carrier plate, and the preparation of the connecting member, the installation of the chip, and the plastic packaging are performed on each side of the double-sided carrier plate.

13. A package body, comprising:
a plastic packaging layer, wherein a depth-controlled groove is defined inside the plastic packaging layer, and one or more first pads are arranged on a side of the plastic packaging layer;
a chip, accommodated upright in the depth-controlled groove; and
a connecting member, wherein one end of the connecting member is connected to a corresponding one of the one or more first pads, and the other end of the connecting member is connected to a side surface of the chip, such that an electrical signal of the chip is lead out of the package body.

14. The package body according to claim 13, wherein the one or more first pads comprise a first sub-pad and a second sub-pad which are arranged on the side of the plastic packaging layer;
the one end of the connecting member is connected to the first sub-pad; and
a component is arranged on a side of the second sub-pad close to the plastic packaging layer.

15. The package body according to claim 14, wherein the component comprises at least one of the chip, a resistance capacitance element, a power source supply, and a switch.

16. The package body according to claim 14, wherein a second dielectric layer is arranged on the side of the plastic packaging layer, a conductive circuit is arranged on a side of the second dielectric layer away from the plastic packaging layer, and a conductive hole is defined on the second dielectric layer;
the conductive circuit is connected to the first sub-pad or the second sub-pad through the conductive hole.

17. The package body according to claim 16, wherein a reinforcing sheet is attached to a side of the plastic packaging layer away from the conductive circuit.

18. The package body according to claim 17, wherein a solder mask layer is attached to a side of the reinforcing sheet away from the conductive circuit.

19. The package body according to claim 13, wherein the plastic packaging layer comprises at least one selected from the group consisting of epoxy resin, polyimide, bismaleimide triazine, and ceramic substrate.

20. The package body according to claim 13, wherein one or more second pads arranged on a side surface of the chip are directly connected to the connecting member exposed through the depth-controlled groove.
